(19) United States
(12) Patent Application Publication
(10) Pub. No.: US 2023/0046856 A1
(43) Pub. Date: Feb. 16, 2023

(54) ENCLOSURE FOR ELECTRICAL INSTALLATIONS

(71) Applicant: Fibox Oy Ab, Espoo (FI)

(72) Inventor: Kenneth WEBER, Espoo (FI)

(21) Appl. No.: 17/787,879

(22) PCT Filed: Dec. 22, 2020
(86) PCT No.: PCT/FI2020/050864

§ 371 Date: Jun. 21, 2022

(30) Foreign Application Priority Data
Dec. 23, 2019 (FI) 20196129

(51) Int. Cl. H02B 1/38; H02B 1/30; H05K 5/02

(52) U.S. Cl. CPC H02B 1/38; H02B 1/303; H05K 5/0221

(57) ABSTRACT

An enclosure for electrical installations includes a bottom and a cover fastened to the bottom by a fastening device including a latch which, supported by a bearing, is turnable in relation to the bottom to open/close the fastening device. An arm is bearing-mounted to the latch. The cover has a detent to receive the arm and to fasten the cover to the bottom by the arm. The detent is located in a recess formed in an edge of the cover. Attached to the arm there is a cover piece to attach to the detent in the recess of the cover. The cover piece includes first and second outer surfaces which at the recess of the cover make the outer surfaces of the cover uniform, such that the discontinuities formed by the recess of the cover on its top and side surfaces are concealed.

### CROSS-REFERENCE RELATED TO PRIOR APPLICATIONS

This application is the U.S. national phase of International Application No. PCT/FI2020/050864 filed Dec. 22, 2020 which designated the U.S. and claims priority to FI 20196129 filed Dec. 23, 2019, the entire contents of each of which are hereby incorporated by reference.

### BACKGROUND OF THE INVENTION

The invention relates to an enclosure for electrical installations, the enclosure comprising a bottom part and a cover fastened to the bottom part by fastening device comprising a latch which, supported by a bearing, may be turned in relation to the bottom part to open and close the fastening device, and an arm body which is bearing-mounted to the latch, whereby the cover has a detent to receive the arm and to fasten the cover to the bottom part by means of the arm.

Enclosures of the type referred to are rather common. A fast opening and closing of the cover in relation to the bottom part may be implemented by the arm. Enclosures often stay at their application sites for years without needing to be disturbed. In this case, if the surroundings are dirty, and the enclosure needs to be opened, the fastening device may be dirty and possibly oxidized to the extent that the opening mechanism of the fastening device fails to work. If an attempt is made to open the dirty opening mechanism with too much force, it may break. Even if a cover of a dirty enclosure could be successfully opened, the enclosure may be difficult to close—and even impossible to close if the fastening mechanism has been damaged when it was opened. Due to the above, if fouling of the fastening mechanism impedes or prevents the opening of an enclosure, the fastening mechanism has to be carefully cleaned prior to opening.

### BRIEF DESCRIPTION OF THE INVENTION

It is a primary object of the invention to eliminate said problem, which is specifically related to enclosures in which the fastening mechanism of a cover comprises an arm.

The object of the invention is achieved with an enclosure which is characterized in that a detent in the cover is located in a recess formed in an edge of the cover, whereby attached to an arm there is a cover piece adapted to attach to the detent in the recess of the cover by means of an arm whereby the cover piece additionally comprises a first outer surface and a second outer surface which at the recess of the cover make the outer surfaces of the cover uniform, when the cover is locked to a bottom part, so that the first outer surface of the cover piece is in the same plane as the top surface of the cover and the second outer surface of the cover piece is in the same plane as the side surface of the cover, and in addition so that the first outer surface and the second outer surface conceal the discontinuities formed by the recess of the cover on the top surface of the cover and correspondingly on the side surface of the cover.

Advantageously, the bottom part of the enclosure has a recess to receive the latch of the fastening device so that the latch is located in the recess of the bottom part. Such a structure reduces the outer dimensions of an enclosure and also makes the enclosure aesthetically stylish. The reduced outer dimensions naturally also allow an easier storage and packing of the enclosures, and also benefit transportation of the enclosures. Because the enclosure has not got any large, protruding fastening device, the chances of them damaging due to impacts are removed, practically speaking. When the bottom part of the enclosure has a recess to receive fastening device, the latch of the enclosure advantageously has two grooves and the cover piece has two grooves, making it possible for an arm of a straightforward shape and taking up little space to turn in relation to the latch, and correspondingly the turning of the cover piece in relation to the latch when the fastening device are opened to release the cover from the fastening device. Due to said grooves, the arm may be shaped such that it protrudes as little as possible from the outer surface of the enclosure.

The recess of the cover has advantageously a hole to fasten the cover to the bottom part with a screw. A screw makes it possible to securely fasten the cover to the bottom part without the danger of the cover detaching from the bottom part, even if the fastening device comprising the latch and arm were to open either unintentionally or due to vandalism. Due to the cover piece, the screw head is protected from dirt and the screw may be easily opened when desired. The screw may naturally be a special screw that is difficult to open because opening requires a special tool to be used.

The fastening device may comprise a body frame part in which the latch bearing is implemented, whereby the body frame part is preferably detachably fastened to a recess formed in a bottom part of the body by means of quick-release means. Such a solution allows the fastening device to be quickly replaced, if for some reason the need arises. However, such a need does not typically exist.

The preferred embodiments of the invention are disclosed in the attached claims 2 to 16.

The biggest advantage of the inventive enclosure is that the enclosure getting dirty during use does not hinder the quick opening of the enclosure because the fastening mechanism keeping the cover of the enclosure closed is protected from dirt. Furthermore, a notable advantage is also that the external appearance of the enclosure at the fastening device is smart as the outer surfaces of the cover are continuous at the fastening device without hindering protrusions or recesses.

### BRIEF DESCRIPTION OF THE DRAWINGS

The invention will now be described in more detail by means of a preferred embodiment thereof and with reference to the accompanying drawing, in which

FIG. 1 shows a general view of the enclosure according to the invention,

FIG. 2 shows a blow-up of a corner of the enclosure shown in FIG. 1 so that the fastening device to fasten the cover to a bottom part are visible, and

FIGS. 3a to 3c illustrate fastening the cover of the enclosure to the bottom part of the enclosure, and

FIG. 4 is a rear view of the fastening device of the enclosure.

### DETAILED DESCRIPTION OF THE INVENTION

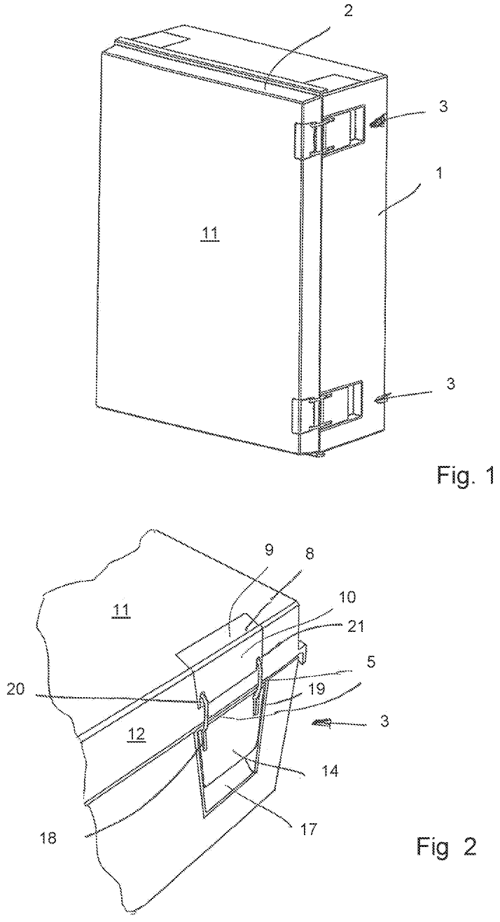

FIG. 1 shows a general view of the enclosure according to the invention. The enclosure comprises a box-like bottom part 1, covered by a box-like cover 2. At one of its edges, the cover 2 is hinged to the bottom part 1 (FIG. 1 does not show the hinges), but instead of the hinge there may be a screw, for example, to fasten the cover to the bottom part. In FIG. 1, reference number 3 indicates easily and quickly openable fastening device to keep the cover 2 closed to the bottom part 1. In other words, the cover 2 is openably fastened to the bottom part 1 with the fastening device 3.

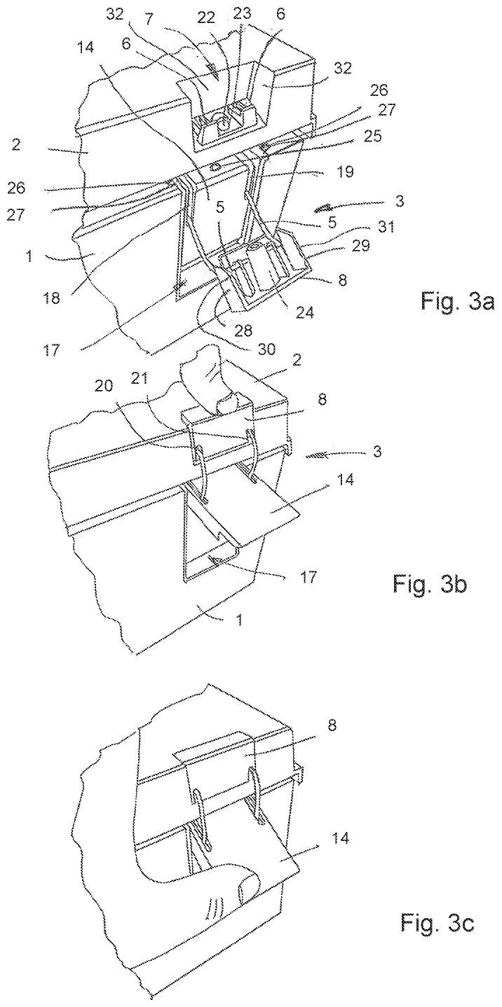

FIG. 2 shows an enlarged view of the fastening device 3 of the cover 2 in the closed position, keeping the cover 2 closed. The fastening device 3 comprise a latch 14, a arm 5, and a cover piece 8. As can be seen in FIG. 2, the cover piece 8 comprises a first planar outer surface 9 which is in the same plane as a top surface 11 of the cover 2, and a second planar outer surface 10 which is in the same plane as an side surface 12 of the cover. The outer surfaces 9 and 10 of the cover piece conceal the recess (recess 7 in FIG. 3a) of the cover 2 so that between the outer surfaces 9 and 10 and the surrounding top surface 11 and correspondingly the side surface 12 of the cover there is no gap which in practise would allow dirt to penetrate to the recess below the cover (see recess 7 in FIG. 3a).

FIGS. 3a to 3c illustrate closing an opened cover 2 with fastening device 3.

In FIG. 3a, the cover 2 is ajar and the cover piece 8 of the fastening device is detached from the cover. In FIG. 3a, reference number 6 denotes a detent in a recess 7 at an edge of the cover 2 to receive the arm 5 of the fastening device. The detent 6 is in the form of a protrusion. The arm 5 rests on the detent 6 when the fastening device 3 are in the closed position. In addition, the recess 7 has a recess 23 which is adapted to receive a protrusion part 24 that the cover piece 8 has. The edges of the recess 23 may provide guiding for the protrusion part 24 when the fastening device 3 are being closed, cf. FIGS. 3b and 3c. The protrusion part 24 is preferably tapered, such as conical. Similarly, the recess 23 may be widening upwards. Walls 32 of the recess 7 guide the cover piece 8 when the fastening device 3 are being closed. For this purpose, the walls 32 defining the recess 7 make the recess narrow downwards, and the cover piece 8 also comprises opposing wall parts 28, 29 which make the cover piece narrow downwards. The wall parts 28, 29 are preferably so formed that their edges 30, 31 rest on the wall 32 of the recess 7 when the cover piece 8 is being inserted downwards into place. Due to the shaping of the recess 7 and cover piece 8 (possibly also due to the recess 23 and protrusion part 24) the cover piece 8 is thus directed precisely in the correct place. When the cover 2 is the closed position, cf FIG. 2, the arm 5 rests on the detent 6 and the protrusion part 24 is located in the recess 7. The detent 6 in the recess of the cover 2 and the recess 23 provide a kind of form locking for the cover piece 8. Deviating from the implementation of the Figure, the details of the form locking may be implemented in various ways, the form locking however always comprising some kind of detent in the cover (cf. detent 6 in FIG. 3a). In addition to a detent, the form locking may comprise other kinds of forms in the recess of the cover (cf. recess 7 in FIG. 3a) and on the inner surface of the cover piece. Therefore FIG. 3a shows one way, only, to establish form locking. The recess 7 has a hole 22, too, which allows the cover 2 to be fastened to the bottom part 1 with a screw (not shown). The body frame part 24 of the fastening device 3 has a hole 25 to receive said screw, see FIG. 3a.

When it is desired to close the cover 2 from the position of FIG. 3a, the cover piece 8 is lifted up and the latch 14 is simultaneously lifted upwards by its lower edge. This way, the cover piece 8 can be lifted over the detent 6 and the cover piece can be adapted into the recess 7 in the cover, cf. FIG. 3b. The cover piece 8 is guided with a thumb in a correct initial position, with the closing of the cover 2 in mind, cf. FIG. 3b, after which the latch 14 in the open position, cf. FIG 3b, is pressed downwards, which is illustrated in FIG. 3c. Then the cover piece 8 lowers controllably to a position where it conceals the recess 7 of the cover 2, cf. FIG. 3c. When the latch 14 is in the closed position of FIG. 2, that is, in a position where the latch is entirely located in the recess 17 of the bottom part 1, the outer surfaces 9 and 10 of the cover piece 8 are in the same plane as the top surface 11 and similarly the side surface 12 of the cover 2. In said closed position, the outer surfaces 8 and 9 of the cover piece 8 conceal the discontinuities formed by the recess of the cover on the top surface 11 and similarly on the side surface 12. In the closed position, the cover piece 8 conceals the recess 7 of the cover 2 so that there is no gap between the circumference of the cover piece 8 and the top surface and side surface 12 of the cover 2 surrounding the cover piece whereby dirt cannot, in any detrimental amount anyway, access the recess.

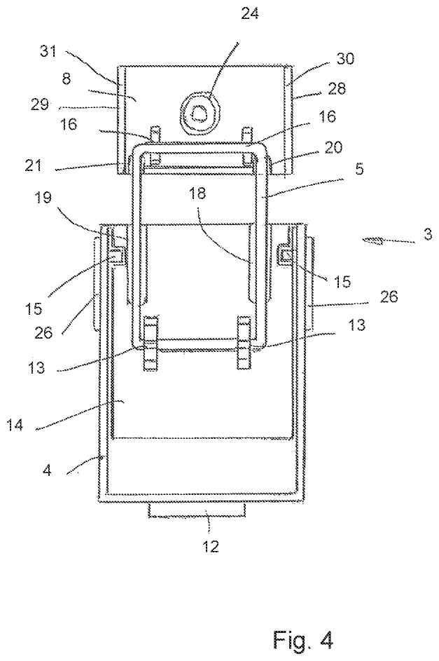

The fastening device 3 include an arm 5 which connects the latch part 14 to the cover piece 8. FIG. 4, which shows the fastening device 3 as seen from the back, that is, from the inside, more closely reveals the structure of the fastening device than the other figures which show the fastening device 3 from the outside.

FIG. 4 shows that the arm 5 of the fastening device 3 is bearing-mounted 13 to the latch 14 and bearing-mounted 16 to the cover piece 8. The latch 14 is bearing-mounted 15 to the body frame part 4. By means of said bearing-mountings 13, 15, and 16, the fastening device 3 can be set in the positions shown in FIGS. 3a to 3c. Because the latch 14 of the fastening device 3 and the body frame part 4 are adapted in a recess 17 in the bottom part 1, and it is further desired that the arm 5 does not protrude obtrusively from the enclosure when the fastening device are in the closed position, the latch 3 has grooves 18, 19 and the cover piece 8 has grooves 20, 21. The grooves 18, 19 allow the wide-ranging turning of the latch 14 in relation to the arm 5, cf. FIGS. 3a to 3c, in which the arm 5 goes in the grooves 18, 19 that the latch has. Similarly, the grooves 20, 21 in the cover piece 8 allow the wide-ranging turning of the cover piece in relation to the arm 5, cf. FIGS. 3a to 3c. As shown in FIG. 2, the arm 5 conceals the grooves 18 to 21 rather well when the fastening device are in the closed position, as a result of which dirt cannot access through the grooves 18 to 21 in any detrimental amount to the recess (see recess 7 in FIG. 3a) under the cover piece 9. As seen from FIG. 2, the arm 5 of the fastening device 3 only protrudes by the material thickness of the arm from the outline of the enclosure.

The body frame part 4 of the fastening device is detachably fastened by quick-release means to the recess 17 of the bottom part 1. For this purpose, at the bottom of the body frame part 4 there is a flexible latch 12 adapted to cooperate with a collar (not shown in the figures) in the recess 17 of the bottom part. When the latch 12 is bent in the direction where it yields perpendicular to the plane formed by the body frame part of the cover part, the latch 12 will be guided behind the collar in the recess 17 and locked against the collar. The body frame part 4 can be removed from the recess 17 by bending the latch whereby the latch is released from the collar. For the body frame part 4 to provide a sturdy fastening for the fastening device 3 to the bottom part 1, the flanks of the body frame part 4 have tongues 26 that settle in matching grooves 27 in the bottom part to establish a tongue-and-groove joint. Tongues

The parts of the fastening device 3 are made of plastic, with the exception of the arm 5. The arm is made of stainless steel.

The details of the invention may be implemented in a number of ways within the scope of the attached claims. Therefore the number of the fastening device 3 in the enclosure may vary. The fastening device 3 do not necessarily have to comprise a body frame part 4, whereby the latch 14 of the fastening device is bearing-mounted 15 directly to the bottom part 1. In the latter case, if the recess 7 in the cover 2 has a hole 22 to receive a screw, the bottom part 1 similarly has a hole or recess to receive the screw. The latch 14 of the fastening device and the body frame part 4 need not necessarily be adapted in the recess 17 in the bottom part 1, although this is highly preferable with the outer dimensions of the enclosure and the risk of the fastening device 3 becoming damaged due to external impacts in mind.

1. An enclosure for electrical installations, the enclosure comprising a bottom part and a cover fastened to the bottom part by fastening device comprising a latch which, supported by a bearing, is turnable in relation to the bottom part to open and close the fastening device, and an arm which ((at its first end)) is bearing-mounted to the latch, whereby the cover has a detent to receive the arm and to fasten the cover to the bottom part by means of the arm, wherein the detent is located in a recess formed in an edge of the cover, whereby attached to the arm there is a cover piece adapted to attach to the detent in the recess of the cover by means of the arm whereby the cover piece additionally comprises a first outer surface and a second outer surface which at the recess of the cover make the outer surfaces of the cover uniform when the cover is locked to the bottom part, so that the first outer surface of the cover piece is in the same plane as the top surface of the cover and the second outer surface of the cover piece is in the same plane as the side surface of the cover, and in addition so that the first outer surface and the second outer surface conceal the discontinuities formed by the recess of the cover on the top surface of the cover and correspondingly on the side surface of the cover, and wherein said first outer surface of the cover piece is planar, and said second outer surface of the cover piece is planar.

2. An enclosure as claimed in claim 1, wherein the arm of the fastening device is bearing-mounted to the cover piece.

3. An enclosure as claimed in claim 1, wherein the bottom part features a recess to receive a latch of the fastening device so that the latch is located in the recess of the bottom part.

4. An enclosure as claimed in claim 3, wherein the latch has two grooves and the cover piece has two grooves to make it possible for the arm to turn in relation to the latch, and correspondingly the turning of the cover piece in relation to the latch to open the fastening device and to release the cover from the fastening device.

5. An enclosure as claimed in claim 4, wherein the fastening device protrude from the outline defined by the bottom part and cover by the arm, at most.

6. An enclosure as claimed in claim 5, wherein the fastening device protrude from the outline defined by the bottom part and cover by the thickness of the arm material of the arm, at most.

7. An enclosure as claimed in claim 1, wherein the cover piece is adapted to attach to the recess in the cover by form locking which comprises said detent.

8. An enclosure as claimed in claim 1, wherein the fastening device comprise a body frame part, and in that the bearing to turn the latch in relation to the bottom part is formed in the body frame part.

9. An enclosure as claimed in claim 8, wherein the body frame part of the fastening device is detachably fastened to the recess in the bottom part of the body.

10. An enclosure as claimed in claim 9, wherein the body frame part of the fastening device is fastened by form locking to the recess in the bottom part.

11. An enclosure as claimed in claim 9, wherein the body frame part of the fastening device is fastened by quick-release means to the recess in the bottom part.

12. An enclosure as claimed in claim 11, wherein the quick-release means comprise a flexible latch adapted to cooperate with a collar in the recess of the bottom part.

13. An enclosure as claimed in claim 11, wherein the quick-release means comprise a groove and tongue joint between the body frame part of the fastening device and the recess of the bottom part.

14. An enclosure as claimed claim 1, wherein the recess of the cover has a hole to fasten the cover to the bottom part by a screw.

15. An enclosure as claimed in claim 1, wherein the detent of the cover comprises, in the recess of the cover, a protrusion part which is adapted to receive the arm of the fastening device.

16. An enclosure as claimed in claim 1, wherein the detent comprises a recess adapted to receive a protrusion part in the cover piece.

17. An enclosure as claimed in claim 1, wherein there are walls defining the recess of the cover, which make the recess narrow downwards, and in that the cover piece comprises opposing wall parts which make the cover piece narrow downwards.

18. (canceled)

19. An enclosure as claimed in claim 1, wherein said top surface of the cover is planar, and said side surface of the cover is planar.

20. An enclosure as claimed in claim 1, wherein said top surface of the cover covers most of the projection of the cover, when examined from direction orthogonal to the top surface, more advantageously more than 80%.

21. An enclosure as claimed in claim 1, wherein said side surface of the cover covers most of the projection of the cover, when examined from direction orthogonal to the side surface, more advantageously more than 80%.
